(19) United States
(12) Patent Application Publication
(10) Pub. No.: US 2006/0214296 A1
(43) Pub. Date: Sep. 28, 2006

(54) Semiconductor device and semiconductor-device manufacturing method

(75) Inventors: Tadahiro Okamoto, Kawasaki (JP); Masamitsu Ikumo, Kawasaki (JP); Eiji Watanabe, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/156,591

(22) Filed: Jun. 21, 2005

(30) Foreign Application Priority Data
Mar. 28, 2005 (JP) 2005-093000

(51) Int. Cl. H01L 23/52

(52) U.S. Cl. 257/751

(57) ABSTRACT

In a semiconductor-device manufacturing method, a metal bump is formed through a plurality of barrier metal layers on an opening which is selectively formed in an insulation layer covering a semiconductor substrate. The metal bump is formed on the plurality of barrier metal layers. A first etching process that selectively removes a lower metal layer among the plurality of barrier metal layers is performed by using an upper metal layer among the plurality of barrier metal layers as a mask. A reflow process that covers an end face of the lower metal layer with a metal that forms the metal bump is performed. After the lower metal layer end face is covered with the metal, a second etching process that removes a barrier metal residue on a surface of the insulation layer in a circumference of the metal bump is performed.

### CROSS-REFERENCE TO RELATED APPLICATIONS

This application is based upon and claims the benefit of priority of Japanese Patent Application No. 2005-093000, filed on Mar. 28, 2005, the entire contents of which are herein incorporated by reference.

### BACKGROUND OF THE INVENTION

1. Field of the Invention

The present invention generally relates to a semiconductor device and its manufacturing method, and more particularly to a semiconductor device and its manufacturing method in which the electrode layer (electrode pad) for external connection is disposed on the semiconductor substrate surface, and a metal bump is formed on the electrode layer via the barrier metal layers.

2. Description of the Related Art

In recent years, in order to enable high-density assembly of the semiconductor chips and packages, the flip chip bonding using the area bumps has come to be widely adopted.

There are various methods for the bump formation. One of the methods for forming the solder bumps which is widely adopted is that the laminated formation of the barrier metal layers is carried out on the electrode layer for external connection of the semiconductor circuit element surface, and the solder bumps are formed on the barrier metal layers through a plating process or the like.

At this time, the surface of the semiconductor chip is covered with the resin layer, such as polyimide, and the surface of the electrode layer is also selectively covered with the resin layer concerned.

In the above-mentioned method, the resist is removed after the solder bump formation, the plating bump is used as a mask, and the wet etching process for the barrier metal layers is performed by applying the etchant (etchant). And, after the etching process, the solder bumps are shaped into the globular form through the reflow heating. For example, see Japanese Laid-Open Patent Application No. 2004-200420 and Japanese Laid-Open Patent Application No. 09-191012.

FIG. 1A through FIG. 1G show the bump formation process according to the conventional semiconductor-device manufacturing method using the plating process.

In the conventional bump formation process using the plating process, as shown in FIG. 1A, the laminated formation of the titanium (Ti) layer, the copper (Cu) layer etc., which serve as the barrier metals for UBM (under bump metal) on the electrode layer (electrode pad) on the semiconductor substrate 1, is carried out by the sputtering method sequentially for each layer.

In the condition before this sputtering, the electrode layer 3 (electrode pad) which is made of aluminum (Al) etc. is disposed on the upper surface of the semiconductor substrate 1 which is made of silicone (Si), and the protective insulation layer 2 which is made of silicon nitride (SiN) etc. is selectively formed on the upper surface of the semiconductor substrate 1.

Furthermore, as a protective film on the insulation layer 2, the polyimide layer 4 (polyimide resin) is formed. In both the insulation layer 2 and the polyimide layer 4, the opening is formed corresponding to the solder bump which will be formed at the predetermined position on the electrode layer 3.

The laminated formation of the titanium layer 5 and the copper layer 6 is carried out sequentially by the sputtering method on the above-mentioned surface of the semiconductor substrate 1.

Subsequently, the photoresist 7 is applied to the copper layer 6 through the spin coating, the exposure/development/curing processing is performed, and as shown in FIG. 1B, the opening, corresponding to the predetermined position of the solder bump formed on the electrode layer 3, is formed in the photoresist layer 7 concerned.

Subsequently, the electrolytic plating processing is performed using the titanium layer 5 and the copper layer 6 as a seed metal (power supply metal layer), and as shown in FIG. 1C, the nickel (Ni) layer 8 is formed in the opening of the photoresist layer 7. This layered product of titanium/copper/nickel serves as the plurality of barrier metal layers.

Subsequently, the titanium/copper/nickel layered product is used as a seed metal and the electrolytic plating processing is performed by using the photoresist layer 7 as a mask. And as shown in FIG. 1D, the tin-silver (SnAg) solder layer 9 is formed on the nickel layer 8. At this time, the solder layer 9 concerned is formed so that it extends on the resist layer 7.

Subsequently, as shown in FIG. 1E, the photoresist 7 is removed using the removing liquid.

Subsequently, as shown in FIG. 1F, the solder layer 9 is used as an etching mask, and the wet etching process is performed to the copper layer 6 and the titanium layer 5.

After an appropriate time, the solder plated layer 9 is fused, and as shown in FIG. 1G, the shaping processing of the solder bump is carried out. That is, the spherical solder bump 9 (solder ball) is formed on the electrode layer 3 of the semiconductor substrate 1.

FIG. 2 shows the structure of the bump portion which is formed according to the plating bump formation process of FIG. 1G.

The barrier metal layers for UBM are required in order to maintain good bonding between the electrode layer 3 and the solder bump 9. The barrier metal layers comprise the first metal layer 5 (Ti layer), the second metal layer 6 (Cu layer) and the third metal layer 8 (Ni layer).

Generally, it is necessary that the barrier metal layers for UBM provide high conductivity, good bonding of the barrier metal layers with the electrode layer 3, and good bonding of the barrier metal layers with the solder bump 9, and that diffusion does not occur between the electrode layer 3 and the solder bump 9.

In the etching process of the titanium layer 5 and the copper layer 6 shown in FIG. 1F, in the above-mentioned plating bump formation process, the amount of side etching of the copper layer 6 is comparatively small, and that amount of side etching is almost equivalent to a quantity which is the same as the film thickness of the copper layer 6 concerned.

However, the amount of side etching of the titanium layer 5 is comparatively large, and that amount of side etching may be a quantity which is 10 times as large as the film thickness of the titanium layer 5.

For this reason, the problem may arise in that the contact area of the solder bump 9 and the electrode layer 3 of the semiconductor chip (LSI) becomes too small and the bonding intensity of the bump becomes too small.

Especially when the area bumps with a narrow pitch are used, the difference between the dimensions of the electrode pads and the outside dimensions of the barrier metal layers for UBM becomes small. If the amount of side etching of the titanium layer is large, the etchant of the titanium layer will reach the electrode layer, so that the electrode layer will be removed or corroded.

On the other hand, if another etchant whose amount of side etching of the titanium layer is comparatively low is applied in order to eliminate the above problem, the residue of titanium is produced on the polyimide layer 4. In such a case, performing a further ashing process for removing the residue substance is needed.

### SUMMARY OF THE INVENTION

An object of the present invention is to provide an improved semiconductor device manufacturing method in which the above-mentioned problems are eliminated.

Another object of the present invention is to provide a semiconductor device and its manufacturing method in which a solder bump is formed through a plurality of barrier metal layers on an electrode layer (electrode pad) disposed on a semiconductor substrate, wherein the amount of side etching of a barrier metal layer is controlled so that good bonding intensity between the electrode layer and the solder bump is maintained.

In order to achieve the above-mentioned objects, the present invention provides a manufacturing method of a semiconductor device in which a metal bump is formed through a plurality of barrier metal layers on an opening which is selectively formed in an insulation layer covering a semiconductor substrate, the manufacturing method comprising the steps of: forming the metal bump on the plurality of barrier metal layers; performing a first etching process that selectively removes a lower metal layer among the plurality of barrier metal layers by using an upper metal layer among the plurality of barrier metal layers as a mask; performing a reflow process that covers an end face of the lower metal layer with a metal that forms the metal bump; and performing, after the lower metal layer end face is covered with the metal, a second etching process that removes a barrier metal residue on a surface of the insulation layer in a circumference of the metal bump.

According to the semiconductor-device manufacturing method of the present invention, the etching of the titanium layer is performed under the condition in which the end face of the UBM barrier metal layers is covered with the solder material, and the titanium layer existing under the copper layer does not contact the etchant. Therefore, it is possible to prevent the amount of side etching of the titanium layer from being too large. For this reason, the etching can be performed without producing the titanium residue on the polyimide layer surface.

### BRIEF DESCRIPTION OF THE DRAWINGS

Other objects, features and advantages of the present invention will be apparent from the following detailed description when read in conjunction with the accompanying drawings.

FIG. 1A, FIG. 1B, FIG. 1C, FIG. 1D, FIG. 1E, FIG. 1F, and FIG. 1G are diagrams for explaining the plating bump formation process according to the conventional semiconductor device manufacturing method.

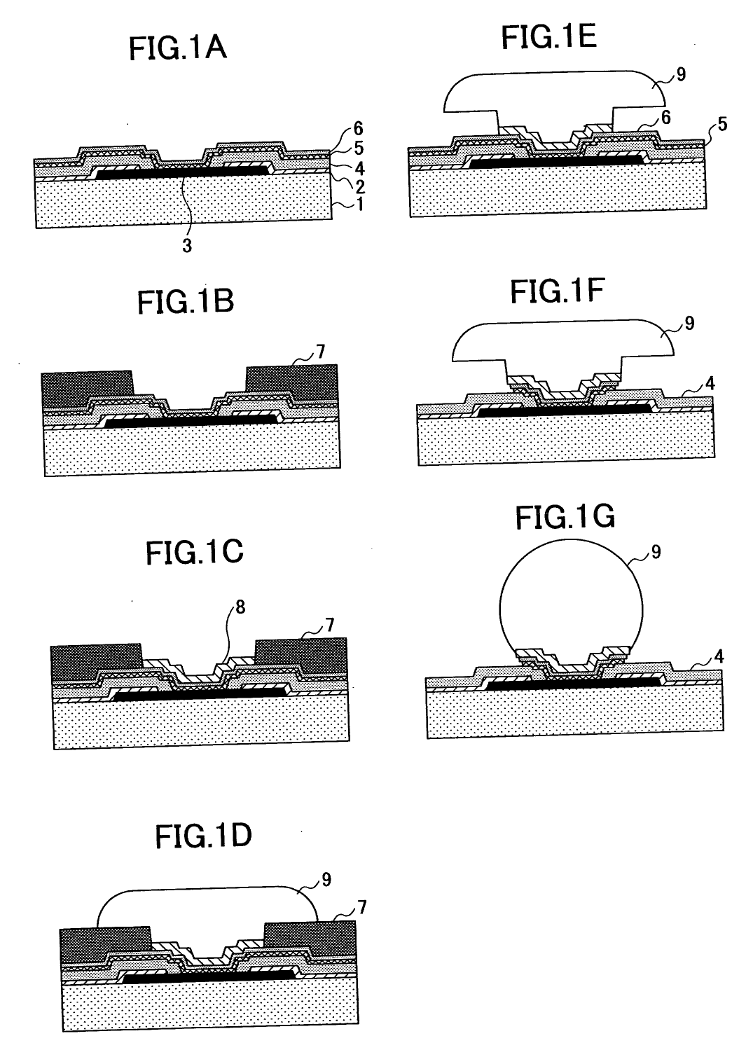

FIG. 2 is a cross-sectional view showing the structure of the bump portion which is formed according to the plating bump formation process of FIG. 1G. FIG. 3A, FIG. 3B, FIG. 3C, FIG. 3D, FIG. 3E, FIG. 3F, FIG. 3G, and FIG. 3H are diagrams for explaining the plating bump formation process according to the semiconductor device manufacturing method in one embodiment of the present invention.

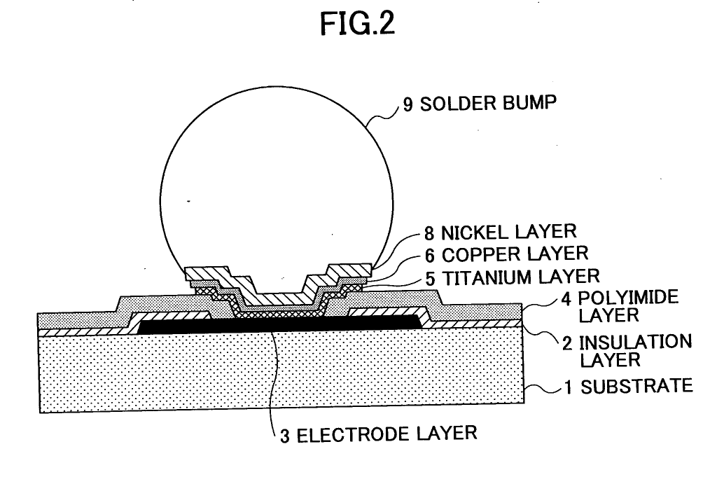

FIG. 4 is a cross-sectional view showing the structure of the bump portion which is formed according to the plating bump formation process of FIG. 3H.

FIG. 5 is an enlarged cross-sectional view showing the structure of the region A of the bump portion indicated by the dotted line in FIG. 4.

FIG. 6 is a diagram for explaining the differences in the barrier metal etching residue between the conventional plating bump formation process and the plating bump formation process of the invention.

FIG. 7A, FIG. 7B, FIG. 7C, FIG. 7D, FIG. 7E, and FIG. 7F are diagrams for explaining the processing flow in the case where the bump formation process according to the transfer bump method is applied to the bump formation process of the invention.

FIG. 8A, FIG. 8B, FIG. 8C, FIG. 8D, FIG. 8E, FIG. 8F, and FIG. 8G are diagrams for explaining the processing flow in the case where the bump formation process according to the paste bump method is applied to the bump formation process of the invention.

FIG. 9A, FIG. 9B, FIG. 9C, FIG. 9D, FIG. 9E, and FIG. 9F are diagrams for explaining the processing flow in the case where the bump formation process according to the screen printing method is applied to the bump formation process of the invention.

### DETAILED DESCRIPTION OF PREFERRED EMBODIMENTS

A description will now be given of the preferred embodiments of the present invention with reference to the accompanying drawings.

FIG. 3A through FIG. 3H show the solder bump formation process according to the semiconductor-device manufacturing method in one embodiment of the invention.

In the plating bump formation process of this embodiment, as shown in FIG. 3A, the laminated formation of titanium (Ti) layer, the copper (Cu) layer etc., which serve as the barrier metals for UBM on the electrode layer on the semiconductor substrate 1, is carried out by the sputtering method sequentially for each layer.

In the condition before this sputtering, the electrode layer 3 (electrode pad) which is made of aluminum (Al) and the insulation layer 2 which is made of silicon nitride (SiN) are selectively formed on the upper surface of the semiconductor substrate 1, and the polyimide layer 4 which is about 2 micrometers thick is formed on the electrode layer 3 and the insulation layer 2.

The opening corresponding to the solder bump which will be formed at the predetermined position on the electrode layer 3 is formed in both the insulation layer 2 and the polyimide layer 4.

The barrier metal layers for UBM for which the laminated formation is carried out by the above-mentioned sputtering method include the titanium (Ti) layer 5 which is about 100 nm thick, and the copper (Cu) layer 6 which is formed on the titanium layer 5 and is about 250 nm thick.

Subsequently, as shown in FIG. 3B, the photoresist layer 7 is applied to the copper layer 6 through the spin coating, and formed thereon. Furthermore, the exposure/development/curing process is performed, and the opening corresponding to the position where the solder bump is formed is formed on the electrode layer 3.

Subsequently, as shown in FIG. 3C, the titanium layer 5 and the copper layer 6 are used as a seed metal for the electrolytic plating, and the nickel (Ni) layer 8 which is about 3.5 micrometers thick is formed on the copper layer 6 within the opening of the photoresist layer 7 by the electrolytic plating process.

That is, the UBM barrier metal layers which comprise the titanium (Ti) layer 5, the copper (Cu) layer 6 and the nickel (Ni) layer 8, arranged in this order from the bottom, are formed on the electrode layer 3 within the opening of the photoresist layer 7.

In the present embodiment, the nickel layer 8 which is the top layer among the UBM barrier metal layers serves to prevent the diffusion of the solder material from the solder ball formed on the nickel layer 8 to the semiconductor substrate, while the copper layer 6 and the titanium layer 5 serve to make the bonding of the nickel layer 8 firm.

Subsequently, as shown in FIG. 3D, the photoresist layer 7 is used as a mask, and the electrolytic plating process of the solder layer (SnAg) is performed by using the barrier metal layers (Ti/Cu/Ni) for UBM as a seed metal.

By performing the electrolytic plating process, the solder plating 9 (SnAg) which is about 40 micrometers thick is formed on the nickel layer 8 among the barrier metal layers for UBM.

After an appropriate time, as shown in FIG. 3E, the removal of the photoresist layer 7 is carried out using the removing liquid.

Subsequently, as shown in FIG. 3F, the wet etching process is performed to the copper layer 6 and the titanium layer 5, which constitute a part of the barrier metal layers for UBM, respectively.

First, the wet etching process to remove the unwanted part of the copper layer 6 is performed with the mixed liquid of acetic acid/oxygenated water/pure water by using the solder plating 9 and the nickel layer 8 as a mask.

Second, the selective etching process to remove the unwanted part of the titanium layer 5 is performed with hydrofluoric acid by using the nickel layer 8 and the copper layer 6 as a mask (the first etching process).

In the present embodiment, the wet etching process to remove the titanium layer 5 is performed with a hydrofluoric acid whose concentration is about 0.1 to 0.5%, so that the titanium layer 5 is etched 100% completely, or etched 95% in the thickness direction of the titanium layer 5.

For this reason, the titanium layer 5 is removed to a degree that some titanium residue remains on the surface of polyimide layer 4 after the first etching process.

Subsequently, as shown in FIG. 3G, the solder layer 9 is fused through the reflow heating, and the bump shaping process is performed so that the solder ball 9 is formed.

By performing the reflow heating process, the exposed end face of the barrier metal layers is covered with the solder which constitutes a part of the solder ball 9.

In the present embodiment, the bump shaping process is performed so that the difference between the diameter of the solder ball 9 and the diameter of the nickel layer 8 located at the bottom among the barrier metal layers is set to be less than 4 micrometers, and the end face of the barrier metal layers for which the laminated formation is carried out is covered with the solder which constitutes a part of the solder ball 9.

Subsequently, as shown in FIG. 3H, under the condition in which the end face of the barrier metal layers is covered with the solder which constitutes a part of the solder ball 9, the etching process to remove the titanium layer 5 is performed again using an ammonium peroxide liquid or a hydrofluoric acid whose concentration is about 0.5%, so that the titanium residue substance on the surface of the polyimide layer 4 is removed (the second etching process).

It is in the condition in which the end face of the barrier metal layers at this time is covered with the solder which constitutes a part of the solder ball 9. Therefore, even if the ammonium peroxide liquid or 0.5% hydrofluoric acid is used as an etchant to remove the titanium residue, it is possible to prevent the amount of side etching of the titanium layer 5, existing under the copper layer 6 among the barrier metal layers, from being too large.

On the other hand, the titanium residue substance which remains on the polyimide layer 4 is removed completely.

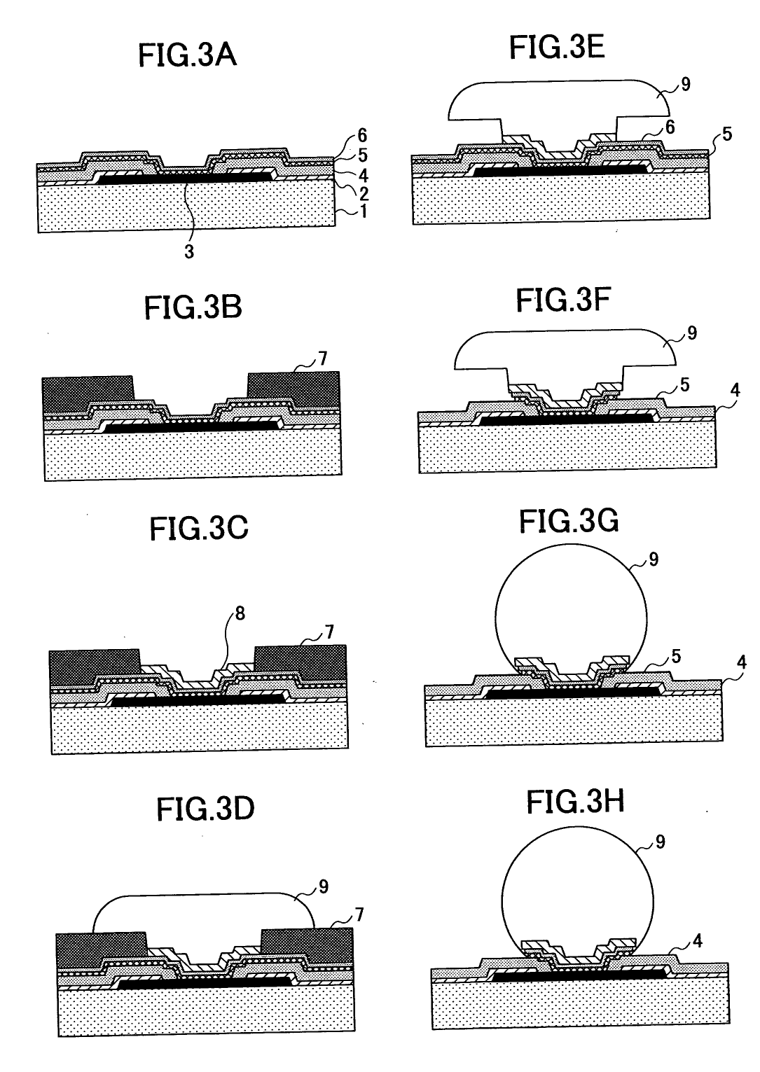

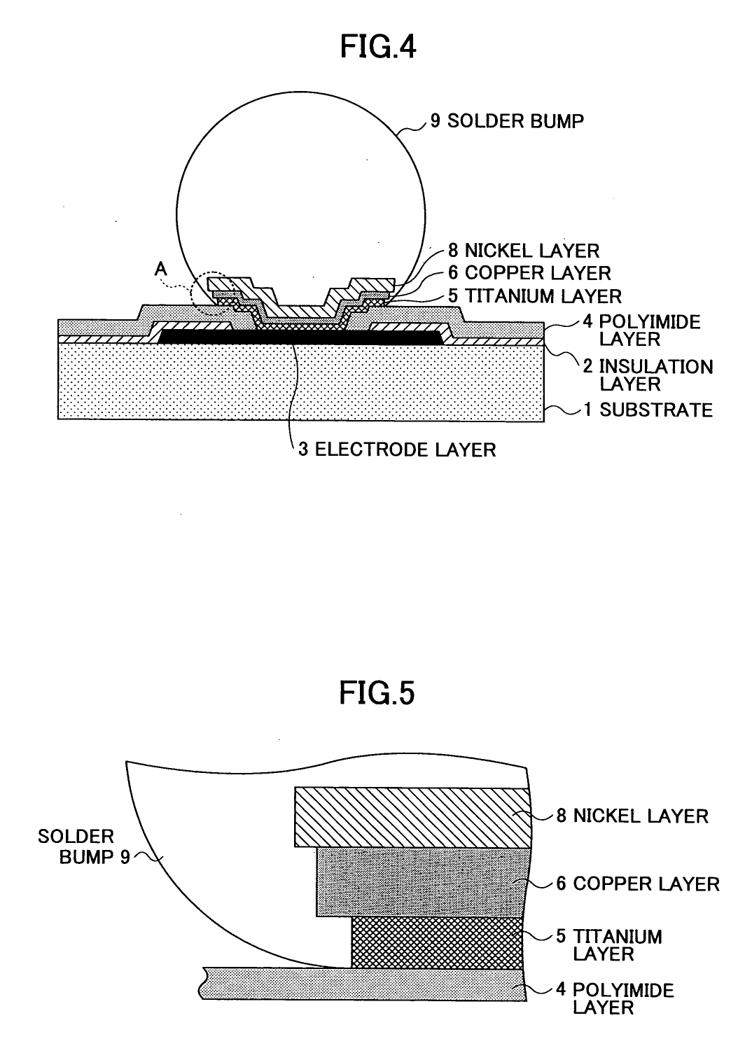

FIG. 4 shows the structure of the bump portion which is formed according to the plating bump formation process of FIG. 3H. FIG. 5 shows the detailed structure of the region A of the bump portion indicated by the dotted line in FIG. 4.

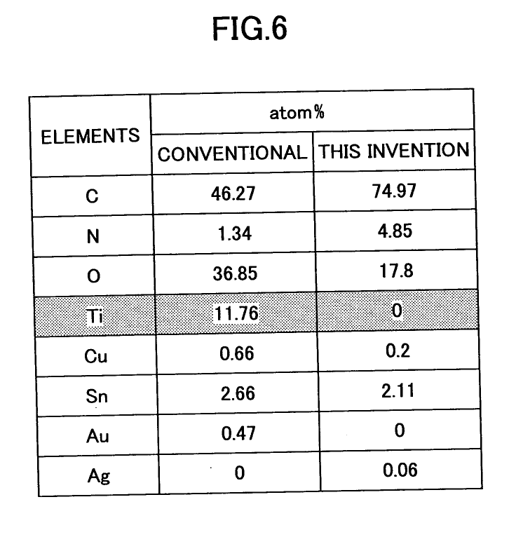

Moreover, FIG. 6 shows the differences in the amount of barrier metal etch residue between the conventional plating bump formation process and the plating bump formation process according to the present invention.

As shown in FIG. 6, the titanium residue substance after the etching of titanium in the conventional plating bump formation process has been 11.76 atom %.

On the other hand, as shown in FIG. 6, in the case where the second etching process of the present embodiment is performed using the ammonium peroxide liquid, the titanium residue substance can be removed completely.

Accordingly, in the above-described embodiment, the etching of the barrier metal layer concerned is performed under the condition where the end face of the UBM barrier metal layers is covered with the solder layer. It is possible to remove completely the titanium residue substance existing on the polyimide layer surface without making the amount of side etching of the titanium layer located at the bottom layer among the barrier metal layers too large.

In the above-mentioned embodiment, the solder bump formation method using the electrolytic plating process has been described. Alternatively, any of the transfer bump method, the paste bump method, the screen printing method may be used instead as the solder bump formation method.

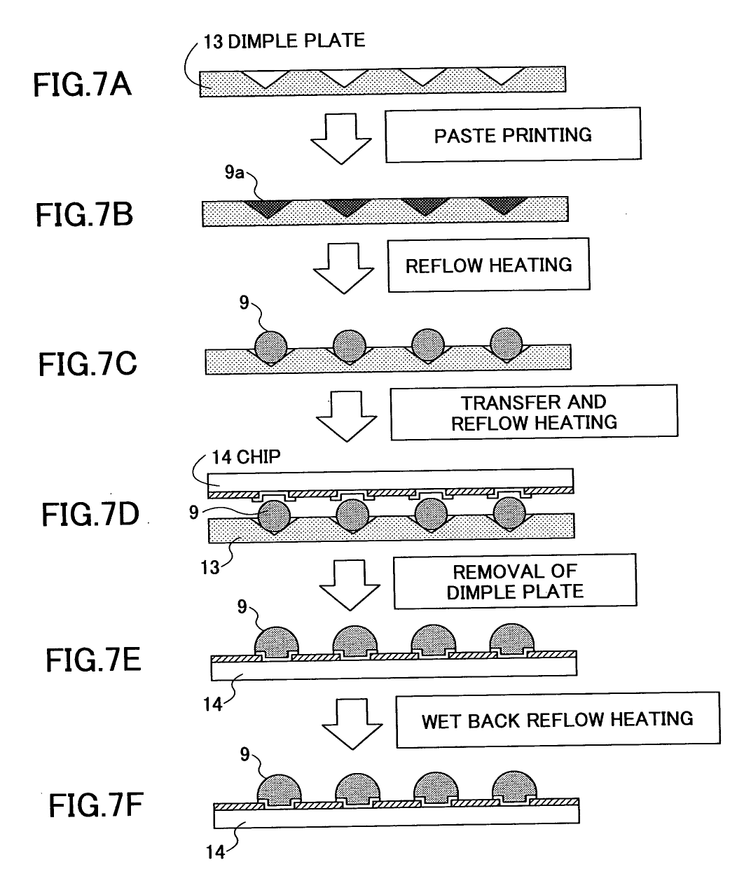

FIG. 7A through FIG. 7F are diagrams for explaining the processing flow in the case where the bump formation process according to the transfer bump method (the dimple plate method) is applied to the plating bump formation process of the present invention.

In the solder bump formation process according to the transfer bump method, as shown in FIG. 7A, the dimple plate 13 in which the slots (dimples) for forming the solder bumps are formed on the upper surface of the plate member is used.

As shown in FIG. 7B, each slot of the dimple plate 13 is filled with the solder paste 9a through the printing method.

Subsequently, as shown in FIG. 7C, the solder paste 9a on the dimple plate 13 is shaped into the ball formation through the reflow heating. Namely, the solder balls 9 are formed on the dimple plate 13.

Subsequently, as shown in FIG. 7D, the solder balls 9 on the dimple plate 13 are transferred to the electrode layer (electrode pads) of the semiconductor substrate (chip) 14, and the solder balls 9 are fixed to the semiconductor substrate 14 by performing the reflow heating again.

Subsequently, as shown in FIG. 7E, the dimple plate 13 is removed from the semiconductor substrate 14. And, as shown in FIG. 7F, the wet back reflow heating is performed so that the solder bumps 9 are fixed to the electrode pads on the semiconductor substrate 14.

It should be noted that, also in the solder bump formation process according to the transfer method, if the first etching process of FIG. 3F, the reflow process of FIG. 3G and the second etching process of FIG. 3H are additionally carried out, the advantageous features which are the same as in the embodiment of FIG. 3H can be realized.

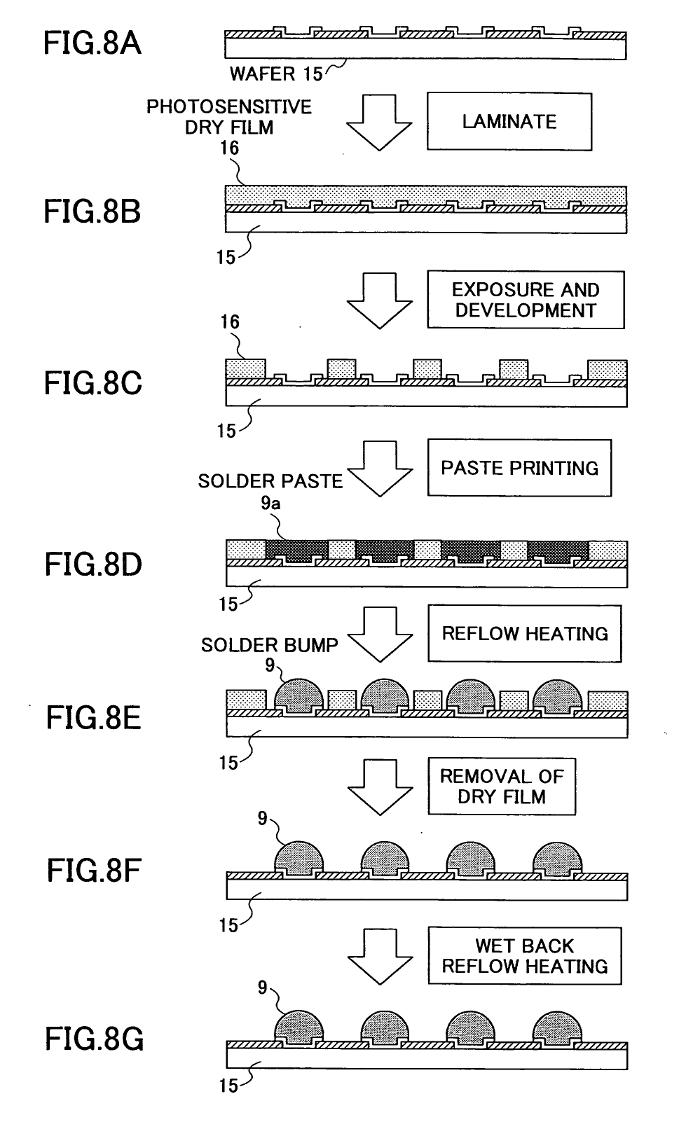

FIG. 8A through FIG. 8G are diagrams for explaining the processing flow in the case where the solder bump formation process according to the paste bump method is applied to the bump formation process of the present invention.

In the solder bump formation process according to the paste bump method, the electrode layer (electrode pad) is formed on the surface of the semiconductor substrate (wafer) 15 as shown in FIG. 8A. And, as shown in FIG. 8B, the photosensitive dry film 16 is formed and laminated on the surface.

Subsequently, as shown in FIG. 8C, the exposure/processing procedure is performed selectively in the photosensitive dry film 16, and the opening corresponding to the position of the electrode layer (electrode pad) formed on the semiconductor substrate 15 is formed.

Subsequently, as shown in FIG. 8D, the opening of the photosensitive dry film 16 on the semiconductor substrate 15 is filled with the solder paste 9a through the printing method.

Subsequently, as shown in FIG. 8E, the solder paste 9a on the electrode layer of the semiconductor substrate 15 surface is fused through the reflow heating, and the solder bump 9 is formed on the electrode layer.

Subsequently, as shown in FIG. 8F, the photosensitive dry film 16 is removed from the semiconductor substrate 15.

And as shown in FIG. 8G, the wet back reflow heating is performed so that the solder bumps 9 are fixed to the electrode layer on the semiconductor substrate 15.

It should be noted that, also in the solder bump formation process according to the paste bump method, if the first etching process of FIG. 3F, the reflow process of FIG. 3G, and the second etching process of FIG. 3H are additionally carried out, the advantageous features which are the same as in the embodiment of FIG. 3H can be realized.

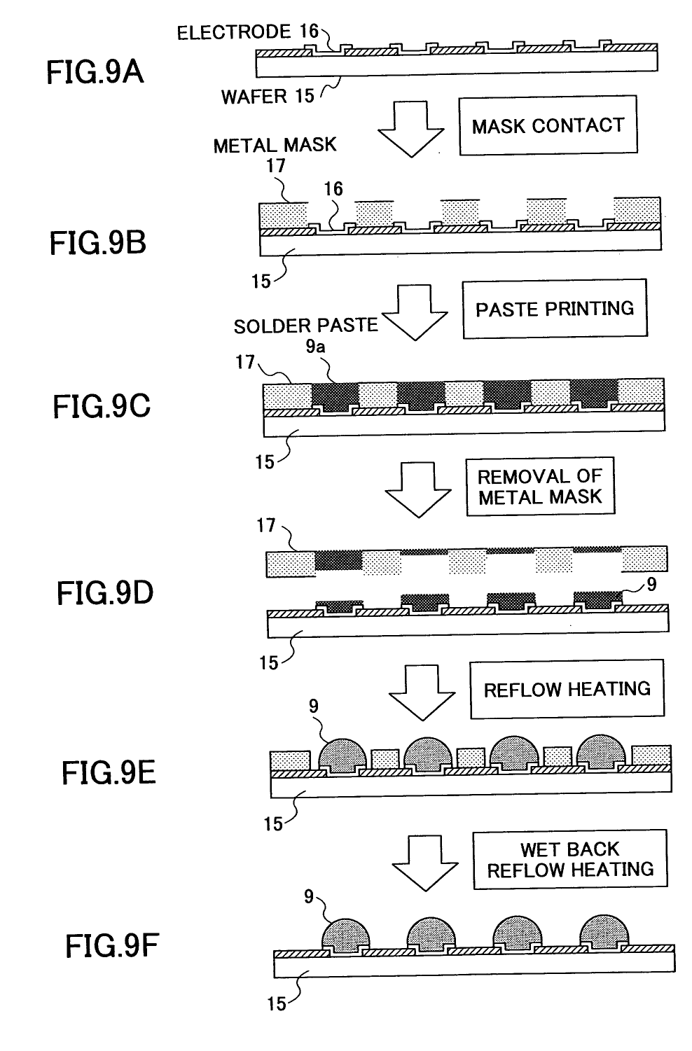

Moreover, FIG. 9A through FIG. 9F are diagrams for explaining the processing flow in the case where the bump formation process according to the screen printing method is applied to the plating bump formation process of the present invention.

In the bump formation process according to the screen printing method, as shown in FIG. 9A and FIG. 9B, the metal mask 17 which has the opening in the position corresponding to the electrode layer 16 is disposed on the semiconductor substrate (wafer) 15 on which the electrode layer (electrode pad) 16 is formed.

Subsequently, as shown in FIG. 9C, each opening of the metal mask 17 on the semiconductor substrate 15 is filled with the solder paste 9a through the screen printing method.

Subsequently, as shown in FIG. 9D, the metal mask 17 is removed from the semiconductor substrate 15.

Subsequently, as shown in FIG. 9E, the solder layer on the electrode 16 of the semiconductor substrate 15 surface is fused through the reflow heating, and the solder bump 9 is formed on the electrode layer 16 of the semiconductor substrate 15.

As shown in FIG. 9F, the wet back reflow heating is performed so that the solder bumps 9 are fixed to the electrode layer 16 on the semiconductor substrate 15.

It should be noted that, also in the solder bump formation process according to the screen printing method, if the first etching process of FIG. 3F, the reflow process of FIG. 3G, and the second etching process of FIG. 3H are additionally performed, the advantageous features which are the same as in the embodiment of FIG. 3H can be realized.

Next, the semiconductor-device manufacturing method in another embodiment of the present invention will be explained.

In the present embodiment, the barrier metal layers for UBM are changed to the four-layer structure. Although the illustrations of the manufacturing process are not given in the drawings, in the present embodiment, the elements which are the same as corresponding elements in the embodiment of FIG. 3H are designated by the same reference numerals.

Similar to the previous embodiment, the electrode layer (electrode pad) 3 which is made of aluminum (Al) etc. and the insulation layer 2 which is made of silicon nitride (SiN) etc. are disposed beforehand on the surface of the semiconductor substrate 1, and the polyimide layer 4 which is about 2 micrometers thick is further formed on the electrode layer 3 and the insulation layer 2.

The opening corresponding to the solder bump which will be formed at the predetermined position on the electrode layer 3 is formed in both the insulation layer 2 and the polyimide layer 4.

Subsequently, on the entire surface including the electrode layer 3 and the polyimide layer 4 on the above-mentioned surface of the semiconductor substrate 1, the laminated formation of the titanium layer 5 as the first metal film (Ti) among the barrier metal layers for UBM and the copper layer 6 as the second metal film (Cu) is further carried out by the sputtering method. The titanium layer 5 is about 100 nm thick, and the copper layer 6 is about 250 nm thick.

Subsequently, the photoresist layer 7 is formed on the copper layer 6 by applying the photoresist through the spin coating, and the exposure/development/curing process is performed, and the opening corresponding to the position of the solder bump formed on the electrode layer 3 is formed.

By performing the photolithographic process, the mask layer (photoresist layer 7) which has the opening with a size equivalent to the size of the barrier metal layers for UBM is formed.

Subsequently, the titanium layer 5 and the copper layer 6 are used as a seed metal for the electrolytic plating process, and the photoresist layer 7 is used as a mask, and the electrolytic plating process is carried out.

On the copper layer 6 within the opening of the photoresist layer 7, the nickel layer 8 (Ni) and the gold layer (Au) which are used as the third and fourth metal films among the barrier metal layers for UBM are formed. Specifically, the nickel layer 8 which is about 3.5 micrometers thick and the gold (Au) layer which is about 0.17 micrometers thick are further formed.

Subsequently, the removal of the photoresist layer 7 is carried out with the removal liquid.

Subsequently, the selective etching process to remove the unwanted part of the copper layer 6 is carried out with an acetic peroxide liquid by using the gold layer and the nickel layer as a mask.

Subsequently, the selective etching process to remove the titanium layer 5 is performed by using the gold layer, the nickel layer and the copper layer 6 as a mask (the first etching process).

In this embodiment, the wet etching process to remove the titanium layer 5 is performed with a hydrofluoric acid whose concentration is about 0.1 to 0.5% so that the titanium layer 5 is etched 100% completely, or etched 95% in the thickness direction of the titanium layer 5.

For this reason, the titanium layer 5 is removed to a degree that some titanium residue remains on the surface of the polyimide layer 4.

Subsequently, the solder layer 9 (SnAg) which is about 80 micrometers thick is formed using the bump formation process (refer to FIG. 7A-7F) according to the transfer method on the gold layer used as the fourth metal film among the barrier metal layers for UBM.

Subsequently, the solder layer 9 is fused through the reflow heating, and the bump shaping processing is performed so that the solder ball 9 is formed (the reflow process).

The reflow process is performed and the exposed end face of the barrier metal layers which comprise the titanium/copper/nickel/gold layers is covered with the solder which constitutes a part of the solder ball 9.

In this embodiment, the above-mentioned reflow process is performed so that the difference between the diameter of the solder ball 9 and the diameter of the gold layer located at the bottom among the barrier metal layers is set to be less than 4 micrometers, and the end face of the barrier metal layers is covered with the solder which constitutes a part of the solder ball 9.

Subsequently, under the condition in which the end face of the barrier metal layers is covered with the solder which constitutes a part of the solder ball 9, the etching process to remove the titanium layer 5 is performed again using an ammonium peroxide liquid or hydrofluoric acid whose concentration is about 0.5% (the second etching process). Therefore, the titanium residue on the surface of the polyimide layer 4 is completely removed.

It is in the condition in which the end face of the barrier metal layers at this time is covered with the solder constitutes a part of the solder ball 9. Therefore, even if the ammonium peroxide liquid or 0.5% hydrofluoric acid is used as an etchant to remove the titanium residue, it is possible to prevent the amount of side etching of the titanium layer 5, existing under the copper layer 6 among the barrier metal layers, from being too large.

On the other hand, the titanium residue substance which remains on the polyimide layer 4 is removed completely. Therefore, according to the semiconductor device manufacturing method of this embodiment, the advantageous features which are the same as in the previous embodiment of FIG. 3H can be realized.

The present invention is not limited to the above-described embodiments, and variations and modifications may be made without departing from the scope of the present invention.

What is claimed is:

1. A manufacturing method of a semiconductor device in which a metal bump is formed through a plurality of barrier metal layers on an opening which is selectively formed in an insulation layer covering a semiconductor substrate, the manufacturing method comprising the steps of:
forming the metal bump on the plurality of barrier metal layers;
performing a first etching process that selectively removes a lower metal layer among the plurality of barrier metal layers by using an upper metal layer among the plurality of barrier metal layers as a mask;
performing a reflow process that covers an end face of the lower metal layer with a metal that forms the metal bump; and
performing, after the lower metal layer end face is covered with the metal, a second etching process that removes a barrier metal residue on a surface of the insulation layer in a circumference of the metal bump.

2. The manufacturing method according to claim 1 wherein the plurality of barrier metal layers are made of any of titanium, copper, nickel, and gold in combination.

3. The manufacturing method according to claim 1 wherein the metal bump is formed through an electrolytic plating process.

4. The manufacturing method according to claim 1 wherein an etching process that removes a copper layer among the plurality of barrier metal layers is performed using a mixed liquid of acetic acid, oxygenated water, and pure water.

5. The manufacturing method according to claim 1 wherein, after an etching process that removes a copper layer among the plurality of barrier metal layers is performed, an etching process that removes a titanium layer as a lowermost metal among the plurality of barrier metal layers is performed using a hydrofluoric acid.

6. The manufacturing method according to claim 1 wherein the reflow process is performed so that an end face of a titanium layer as a lowermost layer among the plurality of barrier metal layers on the insulation layer covering the semiconductor substrate is covered with the metal bump.

7. The manufacturing method according to claim 1 wherein the second etching process is performed by using an ammonium peroxide liquid as an etchant.

8. The manufacturing method according to claim 1 wherein the second etching process is performed by using a hydrofluoric acid as an etchant.

9. The manufacturing method according to claim 1 wherein a process which forms the insulation layer to selectively cover an electrode layer is performed, and a process which carries out a laminated formation of a titanium layer and a copper layer on the insulation layer including the exposed electrode layer is performed.

10. The manufacturing method according to claim 9 wherein a process which forms a photoresist having an opening at a position corresponding to the electrode layer, on the copper layer is performed, a process which forms a nickel layer selectively on the copper layer is performed by using a resist as a mask, and a process which forms a solder bump on the nickel layer is performed.

11. The manufacturing method according to claim 1 wherein a titanium layer and a copper layer among the plurality of the barrier metal layers are covered with the metal bump after the reflow process is performed.

12. The manufacturing method according to claim 1 wherein a difference between a diameter of the metal bump and a diameter of a nickel layer among the plurality of barrier metal layers after the reflow process is performed is less than 4 micrometers.

13. The manufacturing method according to claim 1 wherein a process that forms a polyimide layer is performed so that an opening in an electrode layer is selectively formed.

14. A semiconductor device in which a metal bump is formed through a plurality of barrier metal layers on an opening which is selectively formed in an insulation layer covering a semiconductor substrate, wherein an end face of a lower metal layer among the plurality of barrier metal layers is covered with a metal that forms the metal bump.
